(19) United States
(12) Patent Application Publication
(10) Pub. No.: US 2025/0118936 A1
(43) Pub. Date: Apr. 10, 2025

(54) ELECTRICAL TRANSMISSION EQUIPMENT AND MAINTENANCE PROCEDURES

(71) Applicant: HARTING Electric Stiftung & Co. KG, Espelkamp (DE)

(72) Inventor: Nando HOPPE, Nienstaedt (DE)

(21) Appl. No.: 18/891,600

(22) Filed: Sep. 20, 2024

(30) Foreign Application Priority Data
Oct. 10, 2023 (DE) 10 2023 127 648.4

(51) Int. Cl. H01R 13/688; H01R 13/506; H01R 13/642; H01R 43/00; H05K 7/14

(52) U.S. Cl. CPC H01R 13/688; H01R 13/506; H01R 13/642; H01R 43/002; H01R 2201/04; H05K 7/1492

(57) ABSTRACT

Disclosed is a transmission device which protects at least one computing server connected to it from excessive electrical currents and/or overvoltages. The transmission device has a plug contact, the plug-in area of which can be electrically separated from the cable connection area in the event of a fault, for example by an electrical fuse. In order to minimize the downtime of the respective computing server in the event of a fault, the transmission device is replaced by a back-up transmission device, and the transmission device can be restored and kept as a new back-up transmission device for a further possible fault.'

The invention is based on an electrical transmission device, in particular for computing servers, of the type according to independent claim 1.

In a second aspect, the invention is based on a maintenance method using the electrical transmission device according to claim 1.

Such transmission devices have at least two plug connectors and an electrical transmission line connecting them electrically conductively. They are required to connect one or more computing servers to an electrical power source and/or a plurality of computing servers to each other for electronic data and/or electrical power transmission.

### PRIOR ART

In the prior art, electronic computing units and thus also computing servers used in so-called server farms are becoming ever more powerful and require a corresponding amount of electrical energy. There is no end in sight to this trend.

As a result of this development, the electrical transmission devices used to supply power to the computing servers and/or to transmit power and/or data between the individual computing servers is of particular importance.

On the one hand, the operational reliability of the respective transmission device and also the protection of the computing servers connected to it against possible electrical overvoltages and/or electrical overcurrent is of great importance in the prior art. On the other hand, it is particularly important to minimize the downtime of the computing server in the event of a fault. This applies in particular to complex cabling with a large number of electrical transmission lines.

The disadvantage is that there is still no transmission device in the prior art that takes sufficient account of the aforementioned requirements.

### STATEMENT OF PROBLEM

The object of the invention is to provide a transmission device which protects at least one computing server connected to it from excessive electrical currents and/or overvoltages and also minimizes the downtime of the respective computing server in the event of a possible fault. In particular, this can also apply to a transmission device which has a plurality of electrical transmission lines and connects at least one or, in particular, a plurality of computing servers to an electrical power source and/or to one another.

The fault case can be characterized by the fact that a current flowing through the plug contact has a higher current intensity than a fixed maximum current intensity, which corresponds, for example, to a maximum operating current. This maximum current is defined depending on the conditions of the connected or to be connected computing servers and is suitable for protecting the electronics of the computing servers, in particular their computing unit, from destruction.

Furthermore, the plurality of electrical transmission lines can be at least two, in particular at least three, preferably at least four, particularly preferably at least five, in particular at least six, for example at least seven, in particular at least eight, e.g. at least nine, e.g. ten or even more, e.g. at least eleven or even twelve or more. The plug connector then generally has a corresponding number of plug contacts and the other plug connector has just as many other plug contacts, wherein one of the plug contacts and one of the other plug contacts are each electrically conductively connected to one of the transmission lines. These electrical lines can then be assigned the same and/or different maximum currents as required.

The problem is solved by the subject matter of the independent claims.

An electrical transmission device has at least one electrical transmission line which has two ends, namely a first end and a second end, as well as a plug connector connected to the transmission line at the first end and a further plug connector connected to the transmission line at the second end.

The plug connector has at least one contact carrier and at least one plug contact.

The plug contact has a cable connection area and a plug-in area.

The transmission line has at least one electrical conductor, which is mechanically and electrically conductively connected to the aforementioned cable connection area of the plug contact on the one hand and to a further plug contact of the further plug connector on the other hand-in particular crimped to a further cable connection area of the further plug contact.

The contact carrier has at least one contact receptacle, in which the at least one plug contact is arranged.

The at least one plug contact has a multi-part design. The plug-in area of the plug contact is separate from the cable connection area of the plug contact.

In the operating state, however, the plug-in area is electrically connected to the cable connection area.

The transmission device is set up to separate the aforementioned electrical connection between the plug-in area and the cable connection area in the event of a possible fault.

In particular, the electrical transmission device is intended for computing servers, preferably to supply them with power from an external power source with an operating current with high currents of at least 20 A (“amperes”), preferably at least 25 A, particularly preferably at least 30 A, e.g. at least 35 A and thus, for example, even 40 A and more. For server farms in particular, operating currents with currents of 50 A and more, e.g. for the range from 50 A to 70 A—but of course also more in individual cases—can also be transmitted by the transmission device as intended. The electrical transmission device can also be used between a plurality of computing servers for the transmission of electrical power and/or for electrical data exchange. There may therefore also be transmission devices which-alternatively or additionally-are used not or not exclusively for power transmission, but also or exclusively for electrical data transmission, and then of course with lower currents than the aforementioned currents, i.e. typically well below 1 A, in particular less than 100 mA, i.e. particularly preferably with maximum currents of 20 mA and less, e.g. in the range between 4 mA and 20 mA.

The aforementioned possible fault case can be given by an overcurrent, which therefore has a higher current strength than the maximum permissible operating current. As a rule, this is naturally related to the corresponding transmission voltage in such a way that an overvoltage occurring in the event of a fault that is greater than a maximum permissible operating voltage also results in an overcurrent that is higher than the maximum permissible operating current.

A maintenance method is carried out using such a transmission device. In the event of such a fault, the following steps are carried out:
a. replacing the transmission device with a back-up transmission device identical or at least equivalent to the transmission device;
b. restoring the previously interrupted electrical connection between the plug-in area and the cable connection area;
c. keeping the restored transmission device as a new back-up transmission device for a further possible fault case.

Advantageous embodiments of the invention are given in the dependent claims and the following description.

An important advantage is that the transmission device protects the computing server(s) connected to it from possible overvoltages and/or overcurrents that exceed the specified maximum current strength/maximum operating current. It should be noted here that an overvoltage usually also results in an overcurrent, i.e. it can also be at least indirectly responsible for the destruction (“blowing”) of the electrical fuse.

In particular, the invention is advantageous for a transmission device which has a plurality of, in particular more than two, electrical transmission lines and in particular connects a plurality of, in particular more than two, computing servers to one another and/or to an external electrical power source.

A particular advantage is that each electrical line can be protected separately and without requiring any significant additional space in the aforementioned manner, as the electrical fuse is part of the plug contact, i.e.—figuratively speaking—is arranged in the plug contact itself.

Another additional advantage is that the transmission device provides a particularly high level of operational reliability while taking up little or no additional space.

Another advantage is that the operation, in particular the replacement of the electrical fuses, is very intuitive, as the fuses are part of the respective plug contact, which means that the assignment of the fuses to the associated lines is unambiguous. In the event of damage, the transmission device can be replaced much more quickly than locating and replacing an electrical device fuse, i.e. a fuse located in the computing server.

A further advantage is therefore that in the event of a possible fault, the downtime of the computing server is kept to an absolute minimum by first completely replacing the transmission device with another “back-up” transmission device provided for this purpose, which is at least functionally indistinguishable from the aforementioned transmission device. This can advantageously be reduced to a few seconds, e.g. to less than 40 seconds, in particularly well-prepared cases also to less than 30 or even 20 seconds, e.g. to less than 10 seconds, in particular to less than 8 seconds, preferably to less than 6 seconds and in particularly advantageous cases to even less than 5 seconds, if the back-up transmission device is accessed quickly.

A simple, clear and quick localization of the electrical fuse to be replaced in the dismantled transmission device is particularly advantageous, e.g. by means of a test device adapted to the transmission device in particular. The localization and replacement of the destroyed electrical fuse is then particularly convenient. For example, the test device can have a red and a green LED for each electrical line, wherein the green LED preferably signals correct continuity and the red LED preferably signals an interruption in the electrical connection. The electrical fuse in the relevant plug contact must then be clearly replaced.

In a preferred embodiment, said separation of the electrical connection between the plug-in area and the cable connection area of the plug-in contact can be irreversible. In particular, the plug contact can have an electrical fuse arranged between its cable connection area and its plug-in area and electrically connecting the cable connection area to the plug-in area in the operating state. Irreversible then means that the fuse is destroyed, e.g. if the current is too high, and must be replaced by a new, intact fuse in order to restore the transmission device.

In a preferred embodiment, the electrical fuse has a glass, ceramic or plastic tube which has two ends, namely a cable-connection-side end and a plug-in-side end.

In an advantageous development, the electrical fuse can have two metal caps, namely a cable-connection-side metal cap arranged at the cable-connection-side end, which is mechanically and electrically connected to the cable connection area of the plug contact, and a plug-side metal cap arranged at the plug-in-side end, which is mechanically and electrically conductively connected to the plug area of the plug contact.

The plug-in area and the cable connection area can have bent sheet metal parts as a socket/fuse holder and/or as a spring part in order to interact with the fuse in an elastic and electrically contacting manner.

In the operating state, these two metal caps of the fuse can be electrically conductively connected to each other via a fuse wire running through the glass, ceramic or plastic tube. In the event of a fault, the fuse wire can melt and thus disconnect said electrically conductive connection between the plug-in area and the cable connection area. For this purpose, the fuse wire can have the specified maximum current. In the event of a fault, the fuse wire can be set up to melt as a result of a current of which the current exceeds the maximum current of the fuse, thereby disconnecting said electrically conductive connection between the plug-in area and the cable connection area.

In a further preferred embodiment, the transmission device can have a plurality of transmission lines and a plurality of identical and/or different plug contacts. These plug contacts can be of the same or different design and can therefore also have a plurality of similar or different electrical fuses.

In a further advantageous embodiment, the additional plug contact of the additional plug connector can be formed in one piece. This is advantageous as the electrical cable is already sufficiently protected by the fuse of the plug contact.

The cable connection area of the plug contact and the other plug contact can each be designed as a crimp connection.

In a preferred embodiment, the plug connector can have a plug connector housing. On the cable connection side, the plug connector housing can have a cable inlet with a cable outlet and a cable gland or other strain relief and/or seal. On the plug-in side, the plug connector housing can have a plug-in opening and preferably a locking device, e.g. with one or two locking clips.

In a further advantageous embodiment, the plug connector can have a plug connector modular system, which can in particular be arranged in the plug connector housing, in particular fixed, e.g. screwed in. The plug connector modular system can have a circumferential and cross-sectionally rectangular plug connector modular frame, comprising two opposite narrow-side walls and, at right angles thereto, two longitudinal-side walls, as well as at least one plug connector module received in the plug connector modular frame and held therein or at least receivable and holdable therein. The plug connector modular frame can be inserted into the plug-in opening of the plug connector housing on the plug-in side and screwed or latched into it.

The plug connector module has the contact carrier and at least one plug contact arranged in the at least one contact receptacle of the contact carrier.

The contact carrier has a substantially cuboid insulating body, through which at least part of the contact receptacle runs, as well as holding means moulded onto the insulating body, e.g. latching lugs, for holding the plug connector module in the plug connector modular frame, e.g. in holding windows of the longitudinal-side surfaces of the plug connector modular frame.

Furthermore, the plug connector module has the at least one plug contact arranged in the at least one contact receptacle of the contact carrier.

In a preferred embodiment, the cuboid insulating body of the contact carrier has two narrow-side surfaces opposite one another and two broad-side surfaces opposite one another perpendicular thereto, wherein the narrow-side surfaces each have a width that is less than the width of the two broad-side surfaces. For fastening/holding in the plug connector modular frame, each plug connector module advantageously has a projection, for example a fastening lug, in particular said latching lug, on each of its two narrow-side faces as said holding means, which can also be substantially cuboid in shape. In particular, “substantially” can mean that the fastening lug has a so-called “chamfer” on the plug-in side, by means of which two corners located at the outer end of its longitudinal-side on the plug-in side are bevelled to facilitate insertion into the respective retaining window.

This bevelling can therefore advantageously facilitate the insertion of the latching lugs into said retaining windows of the connector modular frame. In the assembled state, the connector modules can be latched or at least held in the retaining windows by their retaining means.

In a preferred embodiment, the retaining means can therefore be moulded onto two opposite narrow-side surfaces of the insulating body of the respective plug connector module. The two retaining means can differ from each other in terms of their shape in order to ensure correct polarization of the plug connector module in the plug connector modular frame.

Said two retaining means of a plug connector module can differ from one another, for example in their shape and/or their size, in particular by their width, in order to thereby determine the so-called “polarization”, i.e. the orientation of each module in the plug connector modular frame. In other words, in addition to their retaining function, the retaining means, in particular the fastening lugs, can also be used as coding means, in particular also as polarization means, i.e. also for the orientation of the plug connector modules in the plug connector modular frame, due to their different shape and/or size. Furthermore, the retaining windows of the plug connector modular frame of the two longitudinal-side surfaces can be of different sizes in order to determine the polarization of the at least one plug connector module in the plug connector modular frame.

The contact carrier of the plug connector module can be made in a plurality of parts and can have a retaining plate in addition to the aforementioned insulating body. The insulating body can at least partially accommodate the plug contact, e.g. its plug-in area and part of the electrical fuse. For this purpose, the insulating body can have a contact chamber, which is part of the contact receptacle of the contact carrier. In an advantageous embodiment, the retaining plate can then be snapped onto the insulating body in order to fix the plug contact in and/or on the insulating body and the entire plug contact in the contact carrier to absorb insertion and withdrawal forces. In an alternative embodiment, the retaining plate can simply be held on the insulating body by the attachment, as it is arranged with its retaining surface between the attachment and the insulating body.

The plug connector modular frames mentioned above, which serve to accommodate and hold the connector modules, can be available in various designs and, depending on the field of application, can be made of different materials, for example plastic or metal, in particular zinc and/or aluminium alloys, and can be manufactured, for example, by die casting, can be made in one piece from flexible plastic or also in a plurality of parts, for example as an articulated frame. In the latter case, the plug connector modules can engage with their latching lugs in the retaining windows of the side parts of the hinged frame by folding the hinged frame shut and thus be held therein when folded shut. In the case of plug connector modular frames designed as flexible plastic frames, the longitudinal-side surfaces can be pressed apart when the plug connector module is inserted and thus allow the latching lugs to engage in the retaining windows of their opposite longitudinal-side surfaces.

Furthermore, the plug connector modular system can have a plurality of plug connector modules that are accommodated in the plug connector modular frame and are held therein or at least can be accommodated and held therein.

In a preferred embodiment, said contact carrier is thus part of the plug connector module. This plug connector module has said substantially cuboid insulating body, through which at least part of the contact receptacle runs. Furthermore, the plug connector module has retaining means moulded onto its insulating body, e.g. said latching lugs, for holding the plug connector module in said plug connector modular frame. In addition, the plug connector module has at least one plug contact at least partially accommodated in the at least one contact receptacle of the contact carrier.

In particular, each plug connector module can have a plurality of plug contacts and the plug connector can have a plurality of modules accommodated in the modular frame. For example, each plug connector module can have two plug contacts and the plug connector can have two plug connector modules. The connector can then have a total of four plug contacts.

In a preferred embodiment, the retaining means, in particular the latching lugs, can be formed on two opposite narrow-side surfaces of the insulating body and, as already described above, can differ from each other in shape in order to ensure correct polarization of this plug connector module in the plug connector modular frame.

This is particularly advantageous if the plug connector module, as mentioned above, has two plug contacts, for example, wherein the two plug contacts have the same plug-in areas but different electrical fuses, as they are intended for connection to different electronic units of the connected computing server. If the plug connector module is installed incorrectly, an interchange would only come into play in the event of a fault if at least one of the electronic units of the computing server is not sufficiently fused and is therefore destroyed, e.g. by an overcurrent and/or overvoltage.

As already mentioned, the contact carrier can have the retaining plate, which can be latched to the insulating body on the cable connection side in order to hold the at least one plug contact in and/or on the insulating body.

For this purpose, the retaining plate can have a retaining surface with contact feed-through openings. In an advantageous embodiment, the retaining plate can have two retaining arms with latching hooks that are moulded onto the side of the retaining surface and ideally project at right angles from the retaining surface. The insulating body can have counter-latching means on which the retaining arms latch with their latching hooks. Alternatively or additionally, the retaining plate can simply be attached to the insulating body by the attachment by being held in place with its retaining surface between the insulating body and the attachment latched onto it.

In addition, the retaining plate can have at least one latching arm at each of its contact feed-through openings for fixing the respective plug contact in and/or on the insulating body. In particular, two or even three latching arms can be provided for each contact feed-through opening.

The plug contact can protrude from the insulating body on the cable connection side. The plug contact can even protrude from the insulating body on the cable connection side for the most part, in particular with at least a longer portion of its fuse and the cable connection area, while the plug area and possibly a shorter portion of the fuse are arranged in the insulating body. The retaining plate can preferably fix the plug-in area by the latching arms engaging in the insulating body by latching it onto the insulating body on the cable connection side.

In an advantageous development, the plug connector module can also have an attachment in which a further part of the contact receptacle is arranged. In this case, the fuse and the cable connection area of the plug contact can preferably be arranged in this further part of the contact receptacle.

The attachment can have latching tabs with windows at its cable-connection-side end.

In a further advantageous development, the plug connector module can have latching pins for latching onto the latching windows of the latching tabs. These latching pins can be arranged on two opposite broad-side surfaces of the insulating body.

The attachment can also be designed in one piece and have at least two opposite side parts, which are connected to each other via at least one web. In particular, the plug connector module can have at least two plug contacts and the contact carrier can have at least two contact receptacles, wherein the two plug contacts are each accommodated in one of the contact receptacles and the two contact receptacles in the attachment are separated by the web.

The contact carrier can therefore be used to hold the cable connection area, the electrical fuse and the plug-in area together by means of the retaining plate, the insulating body and the attachment.

As mentioned above, the following steps are carried out in the maintenance method using the aforementioned transmission device:
a. replacing the transmission device with a back-up transmission device that is identical or at least equivalent to the transmission device;
b. restoring the previously interrupted electrical connection between the plug-in area and the cable connection area;
c. keeping the restored transmission system as a new back-up transmission device for a further possible fault.

In a preferred embodiment, method step a. can have the following sub-steps:
a1. disconnecting a plug connection between the plug connector of the transmission device and a mating plug connector of the first computing server and disconnecting a further plug connection between the further plug connector of the transmission device and a further mating plug connector of an electrical power source or a second computing server;
a2. establishing a first back-up plug-in connection between a back-up plug connector of the back-up transmission device and a mating plug connector of the first computing server and connecting a further back-up plug-in connection between a further back-up plug connector of the back-up transmission device and the mating plug connector of the electrical power source or the second computing server.

The back-up transmission device can be characterized by the aforementioned features of the transmission device. The transmission device and the back-up transmission device can be designed identically or at least equivalently. The aforementioned transmission device, possibly with at least one replaced electrical fuse, can be used as a back-up transmission device and, conversely, the back-up transmission device can also be used as a transmission device.

In a preferred embodiment, method step b. may include said replacement of the electrical fuse.

In a further preferred embodiment, method step c. includes that the restored transmission device is kept as a back-up transmission device together with other back-up transmission devices which are identical or at least equivalent in order to serve, if necessary, to replace a plurality of transmission devices of a server farm which has a plurality of computing servers.

### EXEMPLARY EMBODIMENT

An exemplary embodiment of the invention is shown in the drawings and is explained in greater detail below. In the drawings:

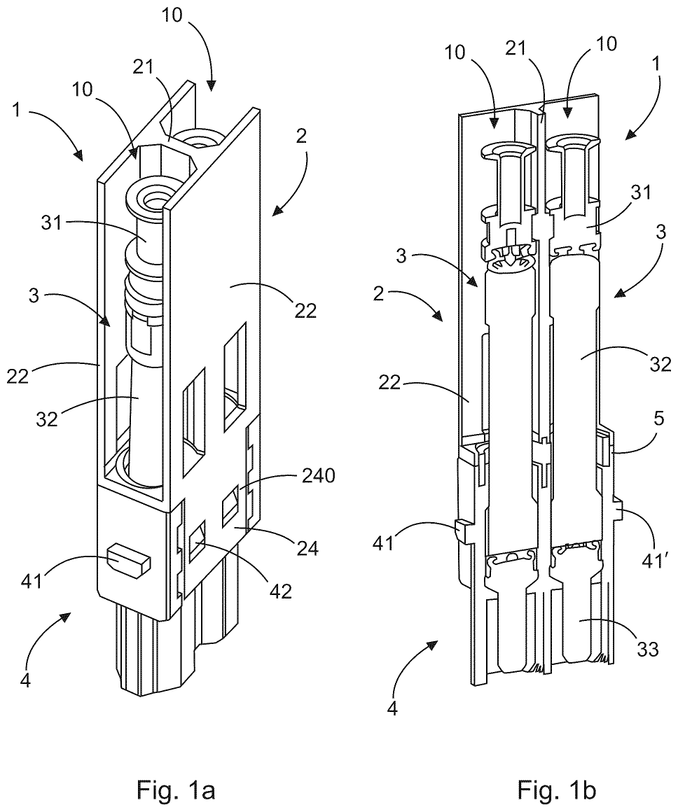

FIGS. 1a, b show a plug connector module in an oblique top view and in a sectional view;

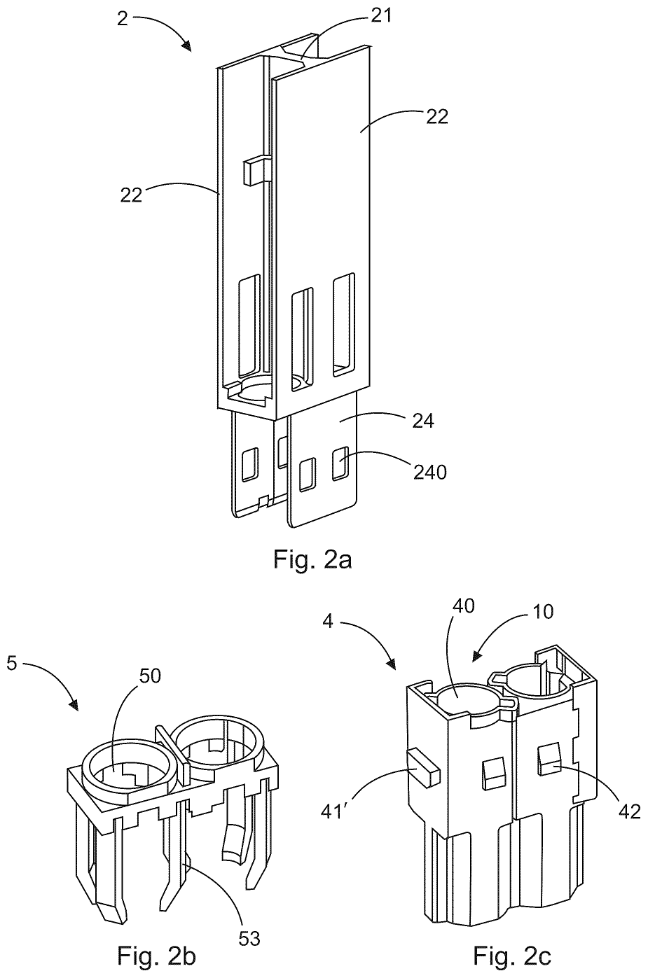

FIGS. 2a-c show an attachment, a retaining plate and an insulating body of the plug connector module;

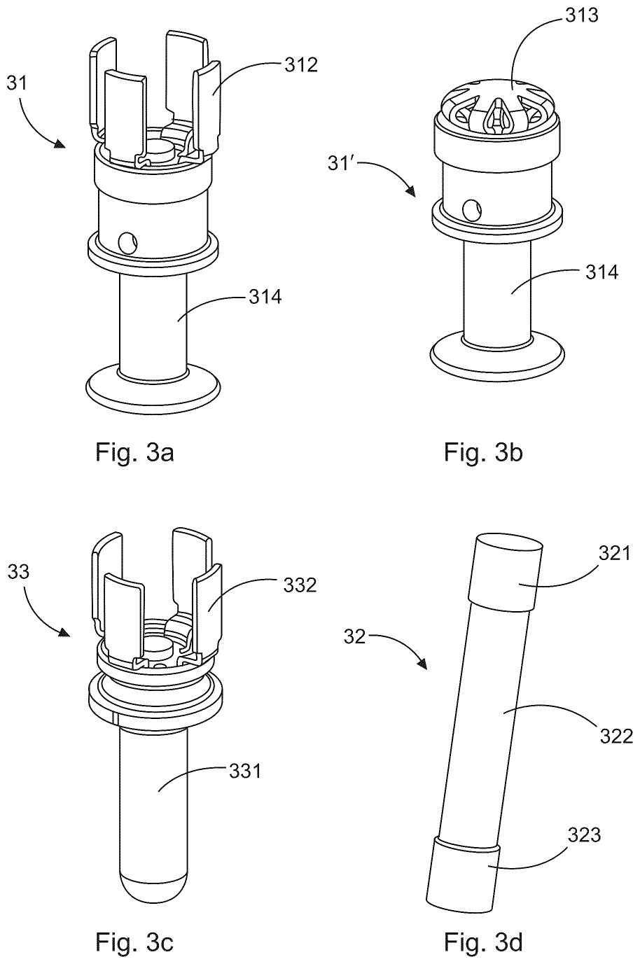

FIGS. 3a, b show two embodiments of a cable connection area;

FIG. 3c shows plug-in area;

FIG. 3d shows an electrical fuse;

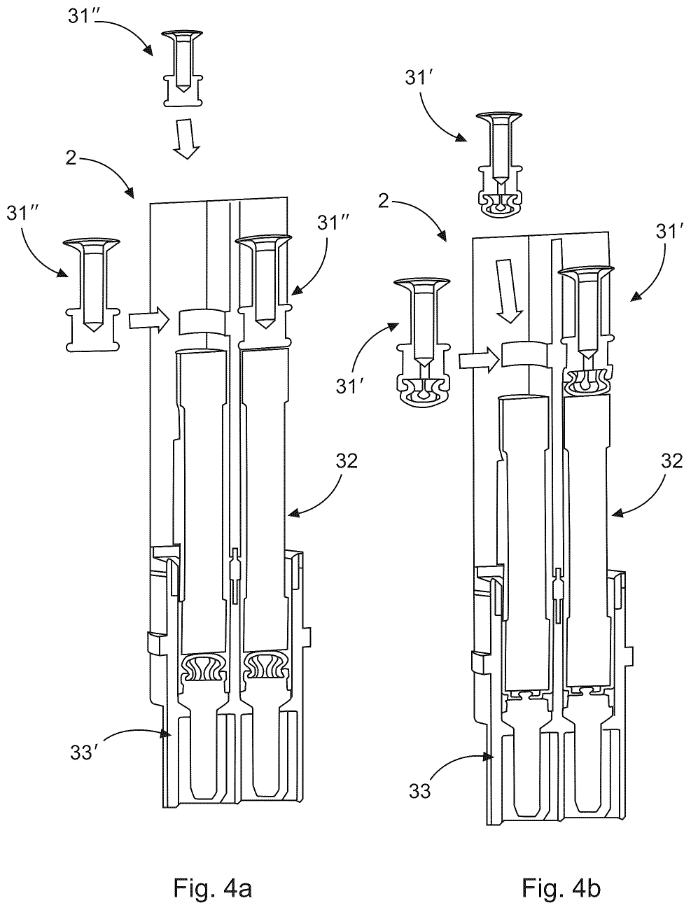

FIGS. 4a, b show a first assembly method for the plug connector module in a first assembly sequence;

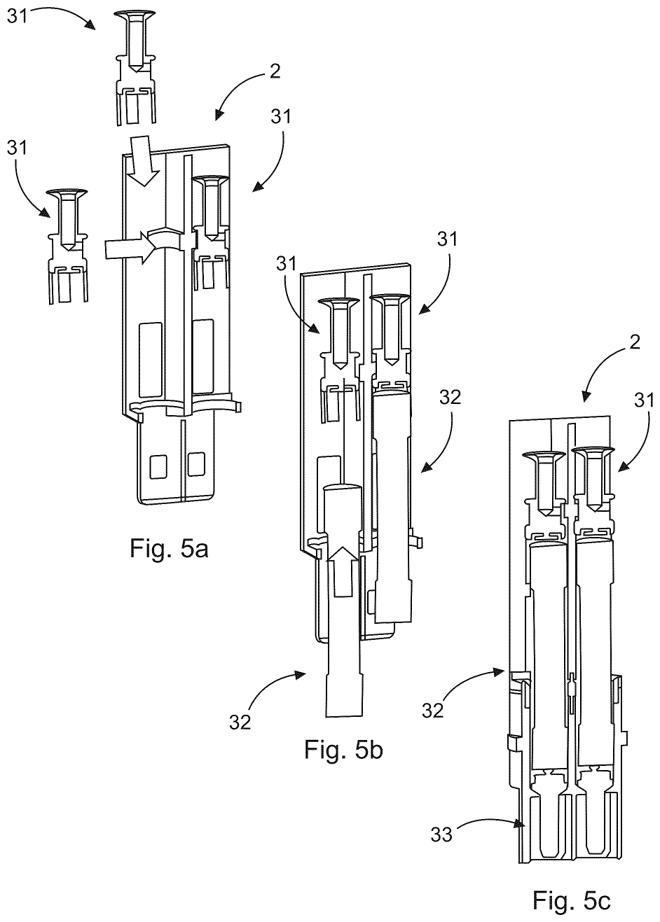

FIGS. 5a-c show a second assembly method;

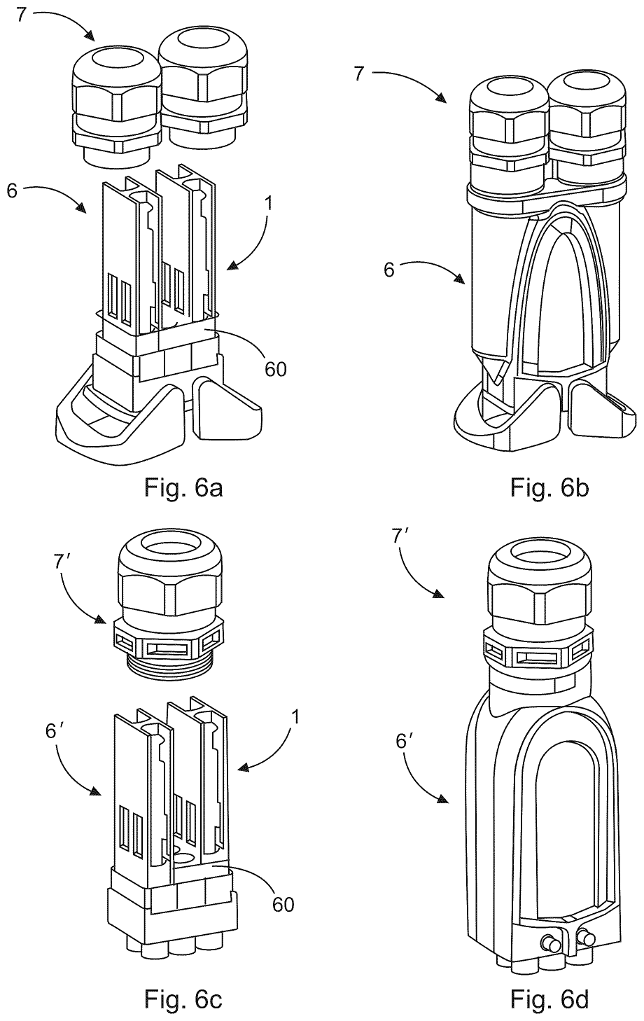

FIGS. 6a-d show two embodiments of a plug-in connector, comprising two plug-in connector modules, each with and without a plug-in connector housing.

Some of the figures contain simplified, schematic representations. In some cases, identical reference signs are used for identical but possibly non-identical elements. Different views of the same elements may be scaled differently. Directional indications such as “left”, “right”, “top” and “bottom” are to be understood with reference to the respective figure and may vary in the individual illustrations in relation to the object shown.

FIGS. 1a and 1b show a plug connector module 1 in an oblique top view and in a sectional view.

The plug connector module 1 has a contact carrier with two contact receptacles 10. Furthermore, the plug connector module has two plug contacts 3, which are arranged in one each of the two contact receptacles 10. The contact carrier has an insulating body 4, a retaining plate 5 latched onto the insulating body 4 and an attachment 2 held on the plug connector module 1, which are also shown as separate parts in the following FIGS. 2a, b and c.

The retaining plate 5 has on the one hand a retaining surface with two contact feed-through openings 50. In addition, the retaining plate 5 has three latching arms 53 at each of its contact feed-through openings 50 for fixing the respective plug contact 3 in and/or on the insulating body 4. The retaining plate 5 is held between the attachment and the insulating body 4 in a form-fitting and frictionally engaged manner.

The plug-in contact 3 has a plurality of separate parts, namely a cable connection area 31, an electrical fuse 32 and a plug-in area 33. The plug-in area 33 is accommodated in the insulating body 4 together with a shorter portion of the electrical fuse 32. The longer part of the contact receptacle 10 is arranged in the attachment 2. Arranged therein are the longer portion of the fuse 32 and the cable connection area 31 of the plug contact 3.

The plug contact 3 thus protrudes out of the insulating body 4 on the cable connection side, but is also partially arranged in a contact chamber 40 of the insulating body 4, namely with its plug-in area 33 and part of its electrical fuse 32. The contact chamber 40 is part of the contact receptacle 10 of the contact carrier.

The attachment 2 is embodied in a single piece and has two opposite side parts 22, which are connected to each other by at least one web 21.

On the plug-in side, i.e. shown at the bottom in the drawing, each of the two side parts 22 has a slightly narrowed, flat extension as a latching tab 24. Two latching windows 240 are arranged in each of these two latching tabs 24. The insulating body 4 is substantially cuboid in shape and has two narrow-side surfaces and two broad-side surfaces, wherein two latching pins 42, each with a cable-connection-side sliding bevel and a plug-in-side latching surface, are arranged on each of its two broad-side surfaces. This allows the attachment 2 to be latched onto the insulating body 4 with its latching windows 240 on the latching pins 42 on the cable connection side.

The attachment 2 is embodied as a single piece and is made of plastic. The two contact receptacles 10 are separated from each other inside the attachment by the web 21. As a result, the two plug contacts 3 in the attachment 2 are insulated from each other.

In FIGS. 3a and 3b, the cable connection area 31, 31′ of the plug contact 3 is shown in two different embodiments, namely in a first embodiment 31 and a second embodiment 31′. There is also a third embodiment 31″, which is not yet shown here, but is shown below in FIG. 4a and described in text form.

In all three embodiments, the connection area 31, 31′, 31″ has a crimp connection 314 on the cable connection side (shown here at the bottom). On the plug-in side (shown here at the top), the connection area has a bent sheet metal part, which is designed as a socket 312 in the first embodiment (FIG. 3a) or as a spring element 113 in the second embodiment (FIG. 3b). In the third embodiment (not shown here), this bent sheet metal part is simply omitted.

FIG. 3c shows the plug-in area of the plug contact 3, which has a contact pin 331 on the plug-in side (shown at the bottom) and a bent sheet metal part on the cable connection side (shown at the top), which is designed as a socket 332. There is also a second embodiment, not shown, in which the bent sheet metal part is designed as a spring element.

The electrical fuse 32 is shown in FIG. 3d.

The electrical fuse 32 has a tube 322, which can also be made of glass, ceramic or plastic, for example. The tube 322 has two ends, namely a cable-connection-side end and a plug-in-side end.

The electrical fuse also has a metal cap 321, 323 at each end of the tube 322, namely a cable-connection-side metal cap 321 arranged at the cable-connection-side end of the tube 322 and a plug-side metal cap 323 arranged at the plug-in-side end of the tube 322. The two metal caps 321, 323 are electrically conductively connected by a fusible conductor, e.g. a wire (not visible).

FIGS. 4a and 4b show a first assembly process.

In FIG. 4a, a cable connection area 31″ in the third embodiment 3″, i.e. without a bent sheet metal part, is inserted laterally into the attachment 2 in an otherwise already mounted plug connector module 1. Alternatively, this cable connection area 31″ can also be inserted on the cable connection side (from above in the drawing). The necessary flexibility is provided by the fact that the plug-in area 33 is of the second embodiment, i.e. has a bent sheet metal part that is designed as a spring element 313.

An identical process is described in FIG. 4b, wherein, however, the plug-in area 33 is in the first embodiment, i.e. the associated bent sheet metal part is designed as a socket 332, and the bent sheet metal part of the cable connection area 31 is designed as a spring element 313, i.e. the cable connection area 31′ is in its second embodiment.

FIGS. 5a to 5c show an assembly process in which the assembly sequence is reversed. I.e. first, as shown in FIG. 5a, the cable connection area 31 in its first embodiment, i.e. with the bent sheet metal part in the form of a socket 312, is pushed into the contact carrier from the left in the drawing or alternatively from above, i.e. from the cable connection side. The fuse 32 is then inserted into the socket 312 of the contact carrier 31 from below. The metal cap 321 on the cable connection side of the fuse 32 is electrically connected to the cable connection area 31. Then the plug-in area 33 is plugged onto the fuse 32 on the plug-in side and electrically conductively connected to the metal cap 323 of the fuse 32 on the plug-in side. Lastly, the insulating body 4 together with the retaining plate 5 is pushed into the attachment 2 from the plug-in side, i.e. from below in the drawing, and latched to it, wherein the retaining plate 5 is held between the attachment 2 and the insulating body 4. The retaining plate 5 fixes the plug-in area 33 permanently in the insulating body 4 with its latching arms 53. As a result, the plug-in contact 3 is held partly in and partly on the insulating body 4 and also in the contact carrier and is also able to absorb plug-in forces.

FIGS. 6a and 6b show a plug connector 7 in a first embodiment, both in a sectional view and from the outside. The plug connector 7 has a plug connector housing 6 and a plug connector modular frame 60 fixed in it on the plug-in side. FIGS. 6c and 6d show the plug connector in a second, comparable embodiment, namely with a slightly different but equivalent plug connector housing 6.

In both embodiments, two plug connector modules 1 are held in the plug connector modular frame 60. Each of the two plug connector modules 1 has two plug contacts 3. Thus, the respective plug connector 7 has four plug contacts 3.

The substantially cuboid insulating bodies 4 of the plug connector modules 1 each have a latching lug 41, 41′ on each of their two narrow-side surfaces, these two latching lugs 41, 41′ being of different widths in order to ensure correct orientation, i.e. polarization, of the plug connector module 1 in the plug connector modular frame 60 and thus in the respective plug connector 7

Even if various aspects or features of the invention are shown in combination in the figures, it is apparent to a person skilled in the art—unless otherwise stated—that the combinations shown and discussed are not the only possible ones. In particular, corresponding units or feature complexes from different exemplary embodiments can be interchanged with one another.

### LIST OF REFERENCE SIGNS

1 plug connector module
10 contact receptacle
2 attachment
21 web
22 side parts
24 latching tab
240 latching window
3 plug contact
31, 31′, 31″ cable connection area
312 socket of the connection area
313 spring element of the connection area
314 crimp connection
32 fuse
321, 323 cable-connection-side, plug-in-side metal cap
322 tube, glass, ceramic or plastic tube
33, 33′ plug-in area
331 contact pin
332 socket of the plug-in area
4 insulating body
40 contact chamber
41, 41′ latching lugs
42 latching pins, fasteners
5 retaining plate
50 contact through-openings
53 latching arms
56 plug connector housing
60 plug connector modular frame
7 plug connector

1. An electrical transmission device, in particular for computing servers, having
at least one electrical transmission line which has two ends, namely a first end and a second end, as well as a plug connector connected to the transmission line at the first end and a further plug connector connected to the transmission line at the second end,
wherein the plug connector has at least one contact carrier and at least one plug contact, wherein the plug contact has a cable connection area and a plug-in area, and wherein the transmission line has at least one electrical conductor, which is mechanically and electrically conductively connected to the first cable connection area on the one hand and to a further plug contact of the further plug connector on the other hand,
wherein the contact carrier has at least one contact receptacle,
in which the at least one plug contact is arranged,
wherein the plug contact has a multi-part design and its plug-in area is separate from its cable connection area,
wherein the plug-in area, in the operating state, is electrically conductively connected to the cable connection area,
wherein
the transmission device is configured to disconnect the aforementioned electrical connection between the plug-in area and the cable connection area in the event of a possible fault.

2. The electrical transmission device according to claim 1, wherein said separation of the electrical connection between the plug-in area and the cable connection area is irreversible.

3. The electrical transmission device according to claim 1, wherein the plug contact has an electrical fuse arranged between the cable connection area and the plug-in area and electrically connecting the cable connection area to the plug-in area in the operating state.

4. The electrical transmission device according to claim 3, wherein the electrical fuse has the following:
a glass, ceramic or plastic tube,
which has two ends, namely
a cable-connection-side end and
a plug-in end
and furthermore has two metal caps, namely
a cable-connection-side metal cap arranged at the cable-connection-side end, which is mechanically and electrically connected to the cable connection area of the plug contact, and
a plug-side metal cap arranged at the plug-in-side end, which is mechanically and electrically conductively connected to the plug area of the plug contact;
wherein, in the operating state, these two metal caps are electrically conductively connected to each other via a fuse wire running through the glass, ceramic or plastic tube.

5. The electrical transmission device according claim 4, wherein the fuse wire has a fixedly specified maximum current and, in the event of a fault, is configured to melt as a result of an electrical current of which the current exceeds this maximum current and thereby disconnects said electrically conductive connection between the plug-in area and the cable connection area.

6. The electrical transmission device according to claim 1, wherein the transmission device has a plurality of transmission lines and a plurality of identical and/or different plug contacts, having a plurality of similar or different electrical fuses.

7. The electrical transmission device according to claim 1, wherein the plug connector has a plug connector modular system, wherein the plug connector modular system has the following:
a plug connector modular frame;
at least one plug connector module received in the plug connector modular frame and held therein or at least receivable and holdable therein, wherein the contact carrier is part of the plug connector module and furthermore has at least the following:
a substantially cuboid insulating body, through which at least part, specifically a contact chamber, of the contact receptacle runs,
a retainer moulded onto the insulating body for holding the plug connector module in or on the plug connector modular frame;
and wherein the plug connector module further has
the at least one plug contact arranged in the at least one contact receptacle of the contact carrier.

8. The electrical transmission device according to claim 7, comprising two retainers moulded onto two opposite narrow sides of the insulating body, and wherein the two retainers differ from each other in terms of their shape in order to ensure correct polarization of the plug connector module in the plug connector modular frame.

9. The electrical transmission device according to claim 7, wherein the contact carrier further has a retaining plate, which is configured to be fastened to the insulating body on the cable connection side in order to hold the at least one plug contact in and/or on the insulating body.

10. The electrical transmission device according to claim 7, wherein the contact carrier additionally has an attachment, in which a further part of the contact receptacle is arranged.

11. The electrical transmission device according to claim 7, wherein the plug connector module has fasteners configured for fastening the attachment to the insulating body, wherein the fasteners are arranged on two opposite broad sides of the insulating body.

12. The electrical transmission device according to claim 10, wherein the attachment is designed in one piece and has at least two opposite side parts, which are connected to each other via at least one web, wherein the transmission device has at least two plug contacts and the contact carrier has at least two contact receptacles, wherein the two contact receptacles in the attachment are separated by the web.

13. A maintenance method using an electrical transmission device according to claim 1, wherein in the event of said fault, the following steps are carried out:
a. replacing the transmission device with a back-up transmission device identical or at least equivalent to the transmission device;
b. restoring the previously interrupted electrical connection between the plug-in area and the cable connection area; and
c. keeping the restored transmission device as a new back-up transmission device for a further possible fault case.

14. The maintenance method according to claim 13,
wherein method step a. comprises the following sub-steps:
a1. disconnecting a plug connection between the plug connector of the transmission device and a mating plug connector of a computing server and disconnecting a further plug connection between the further plug connector of the transmission device and a further mating plug connector of an electrical power source or a second computing server;
a2. establishing a first back-up plug-in connection between a back-up plug connector of the back-up transmission device and the mating plug connector of the computing server and connecting a further back-up plug-in connection between a further back-up plug connector of the back-up transmission device and the further mating plug connector of the electrical power source and/or the second computing server;
and/or
wherein method step b. includes a replacement of the electrical fuse and/or
wherein method step c. includes that the restored transmission device is kept as a back-up transmission device together with other back-up transmission devices which are identical or at least equivalent in order to serve, if necessary, to replace a plurality of transmission devices of a server farm which is distinguished in that it has a plurality of computing servers.
